(19) United States
(12) Patent Application Publication
(10) Pub. No.: US 2012/0144261 A1
(43) Pub. Date: Jun. 7, 2012

(54) ERROR CHECKING AND CORRECTING CIRCUIT, MEMORY SYSTEM COMPISING ERROR CHECKING AND CORRECTING CIRCUIT, AND RELATED METHODS OF OPERATION

(75) Inventors: Ju-Hyung Hong, Suwon-si (KR); Soon-Jae Won, Yongin-si (KR)

(73) Assignee: SAMSUNG ELECTRONICS CO., LTD., Suwon-si (KR)

(21) Appl. No.: 13/241,406

(22) Filed: Sep. 23, 2011

(30) Foreign Application Priority Data
Dec. 7, 2010 (KR) 10-2010-0124450

(51) Int. Cl. H03M 13/29; G06F 11/10

(52) U.S. Cl. 714/755; 714/E11.032

(57) ABSTRACT

An error checking and correcting (ECC) circuit is connected with nonvolatile memories via a plurality of channels. The ECC circuit calculates a first syndrome according to first read data and stores the first syndrome in a first syndrome register block, and calculates a second syndrome according to second read data and stores the second syndrome in a second syndrome register block.

### CROSS-REFERENCE TO RELATED APPLICATIONS

This application claims priority under 35 U.S.C §119 to Korean Patent Application No. 10-2010-0124450 filed Dec. 7, 2010, the disclosure of which is hereby incorporated by reference in its entirety.

### BACKGROUND OF THE INVENTION

Embodiments of the inventive concept relate generally to electronic memory technologies. More particularly, embodiments of the inventive concept relate to an error checking and correcting (ECC) circuit and a memory system incorporating the ECC circuit.

Semiconductor memory devices can be roughly divided into two categories according to whether they retain stored data when disconnected from power. These categories include volatile memory devices, which lose stored data when disconnected from power, and nonvolatile memory devices, which retain stored data when disconnected from power. Examples of volatile memory devices include dynamic random access memory (DRAM) and static random access memory (SRAM), and examples of nonvolatile memory devices include flash memory, read only memory (ROM), magnetoresistive random access memory (MROM), and phase-change random access memory (PRAM).

Flash memory is an especially popular form of nonvolatile memory due to attractive features such as relatively low power consumption, high storage capacity, and an ability to withstand physical shock. Moreover, multiple flash memory devices can be included together in a memory system to provide even higher storage capacity. These flash memory devices can be connected in a parallel configuration allowing relatively efficient read and write operations.

To improve the reliability of a memory system incorporating multiple flash memory devices, ECC circuits can be used to check and correct errors in each of the multiple flash memory devices. However, as the number of flash memory devices in the memory system increases, the amount of area occupied by the ECC circuits tends to increase as well.

### SUMMARY OF THE INVENTION

According to one embodiment of the inventive concept, an ECC circuit comprises first and second syndrome register blocks that receive respective first and second read data transferred via different channels, wherein the first read data comprises multiple units of first sector read data and the second read data comprises multiple units of second sector read data, a syndrome calculating block commonly connected to the first and the second syndrome register blocks, wherein the syndrome calculating block performs first operations based on each unit of the first sector read data to update the first syndrome register block with results of the first operations, and performs second operations based on each unit of the second sector read data to update the second syndrome register block with results of the second operations. The first and second syndromes are determined according to the updated results stored in the first and second syndrome register blocks, and errors in the first and second read data are corrected according to the first and second syndromes.

According to another embodiment of the inventive concept, a memory system comprises a plurality of channels, a plurality of memories connected to the plurality of channels, respectively, and an ECC circuit that performs an error detecting and correcting operation on data transferred via the plurality of channels, wherein the ECC circuit comprises a plurality of register blocks corresponding to the respective channels, and a calculation block commonly connected to the first and the second syndrome register blocks, wherein the calculation block performs combinational logic operations to data received via the respective channels so as to be shared in a time division scheme.

According to another embodiment of the inventive concept, a method is provided for operating a memory system comprising a plurality of nonvolatile memory devices. The method comprises receiving first read data from a first nonvolatile memory device through a first channel, and receiving second read data from a second nonvolatile memory device through a second channel, wherein the first read data comprises multiple units of first sector read data, and the second read data comprises multiple units of second sector read data. The method further comprises transmitting a unit of the first sector read data to a first syndrome register block, and transmitting a unit of the second sector read data to a second syndrome register block. The method further comprises transmitting the unit of the first sector read data to a syndrome calculating block, calculating a first sector syndrome based on the unit of the first sector read data, and transmitting the first sector syndrome to the first syndrome register block and, after calculating the first sector syndrome, transmitting the unit of the second sector read data to the syndrome calculating block, calculating a second sector syndrome based on the unit of the second sector read data, and transmitting the second sector syndrome to the first syndrome register block.

These and other embodiments can reduce the amount of space required to implement error correction in a memory system by using a shared syndrome calculating block for multiple data channels.

### BRIEF DESCRIPTION OF THE DRAWINGS

The drawings illustrate selected embodiments of the inventive concept. In the drawings, like reference numbers indicate like features.

FIG. 1 is a block diagram of a memory system comprising an ECC circuit according to an embodiment of the inventive concept.

FIG. 2 is a block diagram of the ECC circuit and a memory interface illustrated in FIG. 1 according to an embodiment of the inventive concept.

FIG. 3 is a block diagram of a decoding unit for an ECC circuit according to an embodiment of the inventive concept.

FIG. 4 is a timing diagram for a syndrome calculating process of a syndrome calculating block illustrated in FIG. 3 according to an embodiment of the inventive concept.

FIG. 5 is a timing diagram illustrating first read data and second read data corrected by the decoding unit of FIG. 3 according to an embodiment of the inventive concept.

FIG. 6 is a block diagram of a decoding unit for an ECC circuit according to another embodiment of the inventive concept.

FIG. 7 is a timing diagram showing first read data and second read data corrected by the decoding unit of FIG. 6 according to an embodiment of the inventive concept.

FIG. 8 is a block diagram of a decoding unit for an ECC circuit according to yet another embodiment of the inventive concept.

FIG. 9 is a block diagram of a decoding unit for an ECC circuit according to yet another embodiment of the inventive concept.

FIG. 10 is a block diagram of a second internal buffer unit and an encoding unit illustrated in FIG. 2 according to an embodiment of the inventive concept.

FIG. 11 is a timing diagram showing first parity bits and second parity bits generated by the encoding unit illustrated in FIG. 10 according to an embodiment of the inventive concept.

FIG. 12 is a block diagram of a memory system comprising an error detector according to an embodiment of the inventive concept.

FIG. 13 is a block diagram of an error detector and a memory interface illustrated in FIG. 12 according to an embodiment of the inventive concept.

FIG. 14 is a block diagram showing a first internal buffer unit and an error detection code (EDC) decoding unit illustrated in FIG. 13 according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

In the description that follows, the terms first, second, third, etc. may be used to describe various features, but the described features should not be limited by these terms. Rather, these terms are merely used to distinguish one feature from another. Accordingly, a first feature discussed below could be termed a second feature without departing from the teachings of the inventive concept.

Spatially relative terms, such as “beneath”, “below”, “lower”, “under”, “above”, “upper” and the like, may be used herein for ease of description to indicate one feature's relationship to another feature. The spatially relative terms are intended to encompass different orientations of the device in use or operation in addition to the orientation depicted in the figures. For example, if the device in the figures is turned over, features described as “below” or “beneath” or “under” other features would then be oriented “above” the other features. Thus, the terms “below” and “under” can encompass both an orientation of above and below. The device may be otherwise oriented (rotated 90 degrees or at other orientations) and the spatially relative descriptors used herein interpreted accordingly. In addition, where a feature is referred to as being “between” two features, it can be the only feature between the two features, or one or more intervening features may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, but do not preclude the presence or addition of one or more other features. As used herein, the term “and/or” includes any and all combinations of one or more of the associated listed items.

Where a feature is referred to as being “on”, “connected to”, “coupled to”, or “adjacent to” another feature, it can be directly on, connected, coupled, or adjacent to the other feature, or intervening features may be present. In contrast, where a feature is referred to as being “directly on,” “directly connected to”, “directly coupled to”, or “immediately adjacent to” another feature, there are no intervening features present.

Unless otherwise defined, all terms (including technical and scientific terms) used herein have the same meaning as commonly understood by one of ordinary skill in the art. In addition, terms such as those defined in commonly used dictionaries should be interpreted as having a meaning that is consistent with their meaning in the context of the relevant art and/or this description and will not be interpreted in an idealized or overly formal sense unless expressly so defined herein.

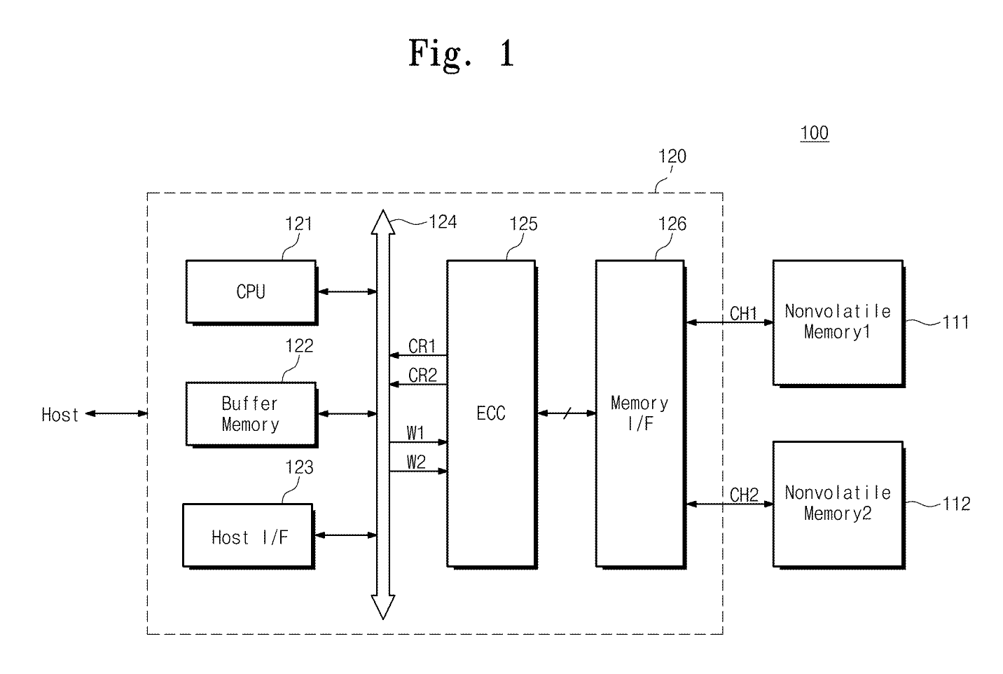

FIG. 1 is a block diagram of a memory system 100 comprising an ECC circuit according to an embodiment of the inventive concept.

Referring to FIG. 1, memory system 100 comprises first and second nonvolatile memories 111 and 112 and a memory controller 120.

First and second nonvolatile memories 111 and 112 are connected to memory controller 120 via first and second channels CH1 and CH2, respectively. Although FIG. 1 shows two nonvolatile memories 111 and 112, memory system 100 could be modified to include three or more nonvolatile memories. In addition, although FIG. 1 shows each nonvolatile memory connected to a one channel, memory system 100 could be modified so that multiple nonvolatile memories are connected to a single channel. Where multiple nonvolatile memories are connected to a single channel, a read or write operation may be carried out selectively with respect to one of the multiple nonvolatile memories.

Memory controller 120 is connected with a host (not shown) and nonvolatile memories 111 and 112. Memory controller 120 is configured to access nonvolatile memories 111 and 112 in response to a request from the host. For example, memory controller 120 can be configured to control read, write, erase, and background operations of nonvolatile memories 111 and 112. Additionally, memory controller 120 can be configured to provide an interface between nonvolatile memories 111 and 112 and the host. In some embodiments, memory controller 120 is configured to drive firmware for controlling nonvolatile memories 111 and 112.

Memory controller 120 can simultaneously access first and second nonvolatile memories 111 and 112 via first and second channels CH1 and CH2. For example, in a read operation, memory controller 120 can send an address via first and second channels CH1 and CH2 to nonvolatile memories 111 and 112 and receive data corresponding to the address from nonvolatile memories 111 and 112.

Memory controller 120 comprises a CPU 121, a buffer memory 122, a host interface 123, a bus 124, an ECC circuit 125, and a memory interface 126.

CPU 121 controls overall operations of memory controller 120, and it is connected with buffer memory 122, host interface 123, and ECC circuit 125 via bus 124. Buffer memory 122 can be used as a working memory of CPU 121, a cache memory between nonvolatile memories 111 and 112 and the host, or a buffer memory between nonvolatile memories 111 and 112 and the host. In some embodiment, buffer memory 122 comprises an SRAM or a DRAM, and in some embodiments, error-corrected data from ECC circuit 125 is stored in buffer memory 122 so that it can be sent to the host.

Host interface 123 implements a protocol for performing data exchange between host and memory controller 120. In some embodiments, host interface 123 implements a standard interface protocol such as a universal serial bus (USB) protocol, a multimedia card (MMC) protocol, a peripheral component interconnect (PCI) protocol, a PCI-express protocol, an advanced technology attachment (ATA) protocol, a serial-ATA (SATA) protocol, a parallel-ATA (PATA) protocol, a small computer small interface (SCSI) protocol, an enhanced small disk interface (ESDI) protocol, or an integrated drive electronics (IDE) protocol.

In a write operation, ECC circuit 125 receives write data W1 and W2 to be stored in first and second nonvolatile memories 111 and 112. It is assumed that first and second write data W1 and W2 are stored in first and second nonvolatile memories 111 and 112, respectively. ECC circuit 125 generates parity bits based on first and second write data W1 and W2. First write data W1 and corresponding parity bits are stored in first nonvolatile memory 111, and second write data W2 and corresponding parity bits are stored in second nonvolatile memory 112.

In a read operation, ECC circuit 125 receives read data from nonvolatile memories 111 and 112. It is assumed that the first read data and the second read data are received from first nonvolatile memory 111 and second nonvolatile memory 112, respectively. ECC circuit 125 corrects errors in the first and second read data and outputs first and second corrected read data CR1 and CR2. First and second corrected read data CR1 and CR2 are transferred to the host.

Memory interface 126 provides an interface between nonvolatile memories 111 and 112 and memory controller 120. Memory interface 126 accesses nonvolatile memories 111 and 112 in parallel. Memory interface 126 can be implemented to accommodate different types of nonvolatile memories 111 and 112. For example, where nonvolatile memories 111 and 112 are NAND/NOR flash memories, memory interface 126 can provide a NAND/NOR flash interface.

In some embodiments, memory controller 120 and nonvolatile memories 111 and 112 are integrated in a single semiconductor device, such as a memory card. For example, memory controller 120 and nonvolatile memories 111 and 112 can be integrated in a single semiconductor device to form a memory card such as a PC or PCMCIA card, a SmartMedia card, a memory stick, a multimedia card (e.g., an MMC, RS-MMC, or MMCmicro card), a secured digital card (e.g., a SD, miniSD, microSD, or SDHC card), or a universal flash storage (UFS) device.

Memory controller 120 and nonvolatile memories 111 and 112 can be integrated in a single semiconductor device to form a solid state drive (SSD). Where memory system 100 is used as an SSD, the operating speed of the host connected with memory system 100 may be improved remarkably.

In some embodiments, memory system 100 is used as computer, portable computer, ultra mobile PC (UMPC), workstation, net-book, PDA, web tablet, wireless phone, mobile phone, smart phone, e-book, portable multimedia player (PMP), digital camera, digital audio recorder/player, digital picture/video recorder/player, portable game machine, navigation system, black box, 3-dimensional television, a device capable of transmitting and receiving information at a wireless environment, one of various electronic devices constituting a home network, one of various electronic devices constituting a computer network, one of various electronic devices constituting telematics network, an RFID device, or one of various electronic devices constituting a computing system.

Nonvolatile memories 111 and 112 or memory system 100 can packaged in various types of package configurations, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline integrated circuit (SOIC), shrink small outline package (SSOP), thin small outline package (TSOP), system in package (SIP), multi chip package (MCP), wafer-level fabricated package (WFP), or wafer-level processed stack package (WSP).

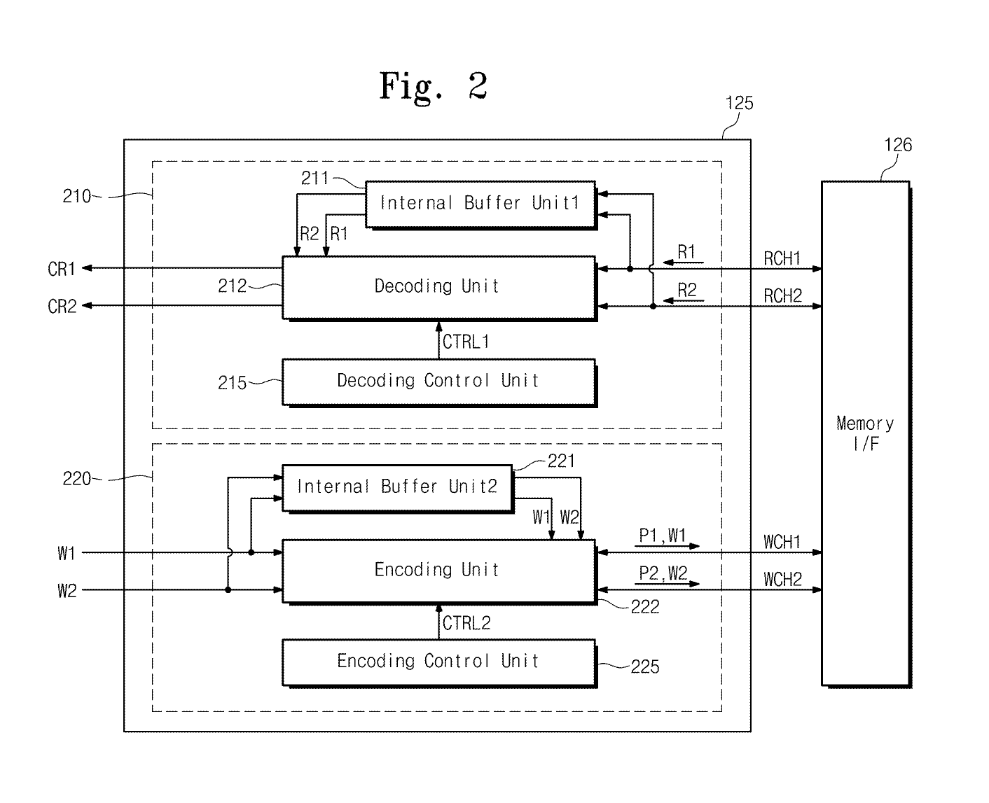

FIG. 2 is a block diagram of ECC circuit 125 and memory interface 126 of FIG. 1 according to an embodiment of the inventive concept.

Referring to FIG. 2, ECC circuit 125 comprises an ECC decoder 210 and an ECC encoder 220.

ECC decoder 210 is connected with memory interface 126 via first and second read channels RCH1 and RCH2, and it receives the first and second read data R1 and R2 via first and second read channels RCH1 and RCH2.

ECC encoder 220 is connected with memory interface 126 via first and second write channels WCH1 and WCH2, and it transmits first and second data W1 and W2 with first and second parity bits P1 and P2 via first and second parity channels WCH1 and WCH2, respectively.

ECC decoder 210 comprises a first internal buffer unit 211, a decoding unit 212, and a decoding control unit 215. First internal buffer unit 211 stores first and second read data R1 and R2 received via first and second read channels RCH1 and RCH2, respectively. First internal buffer unit 211 sends first and second read data R1 and R2 to decoding unit 212. In some embodiments, first internal buffer unit 211 receives and stores first and second read data R1 and R2 in units of 512 bytes.

Decoding unit 212 receives first and second read data R1 and R2 via first and second read channels RCH1 and RCH2, respectively. Decoding unit 212 corrects errors in first and second read data R1 and R2 and generates first and second corrected read data CR1 and CR2. Decoding unit 212 can calculate error locations, for example, using a known type of error correction code such as a BCH code, an RS code, a turbo code, or an LDPC code. Errors can be corrected in first and second read data R1 and R2 based on the calculated error locations.

Decoding control unit 215 transfers a decoding control signal CTRL1 to decoding unit 212. The timing of internal operations of decoding unit 212 is controlled according to decoding control signal CTRL1. Decoding unit 212 detects and corrects errors in first and second read data R1 and R2 in response to decoding control signal CTRL1.

ECC encoder 220 comprises a second internal buffer unit 221, an encoding unit 222, and an encoding control unit 225. Second internal buffer unit 221 temporarily stores first and second write data W1 and W2. Encoding unit 222 calculates parity bits for first and second write data W1 and W1, and then second internal buffer unit 221 provides first and second write data W1 and W2 to encoding unit 222.

Encoding unit 222 receives first and second write data W1 and W2 to calculate corresponding first and second parity bits P1 and P2. In some embodiments, encoding unit 222 generates parity bits using an error correction code such as a BCH code, an RS code, a turbo code, or an LDPC code.

Encoding unit 222 receives first and second write data W1 and W2 from second internal buffer unit 221, and it transmits first parity bits P1 and first write data W1 via first write channel WCH1. First parity bits P1 and first write data W1 are stored together in first nonvolatile memory 111. Encoding unit 222 transmits second parity bits P2 and second write data W2 via second write channel WCH2. Second parity bits P2 and second write data W2 are stored together in second nonvolatile memory 112.

In some embodiments, first parity bits P1 and first write data W1 are stored in memory cells connected with a word line in first nonvolatile memory 111. It is assumed that first parity bits P1 and first write data W1 constitute first read data R1. Where first read data R1 is received in a read operation, ECC decoder 210 corrects errors in first write data W1 using first parity bits P1.

Encoding control unit 215 generates an encoding control signal CTRL2 to control the timing of an internal operation of encoding unit 222. Encoding unit 222 generates first and second parity bits P1 and P2 in response to encoding control signal CTRL2.

Memory interface 126 is connected with first and second read channels RCH1 and RCH2 and first and second write channels WCH1 and WCH2. In a read operation, memory interface 126 connects first read channels RCH1 and RCH2 to first and second channels CH1 and CH2, respectively. Accordingly, in the read operation, ECC decoder 210 is connected electrically with first and second nonvolatile memories 111 and 112.

In a write operation, memory interface 126 connects first write channels WCH1 and WCH2 to first and second channels CH1 and CH2, respectively. Accordingly, in the write operation, ECC encoder 220 is connected electrically with first and second nonvolatile memories 111 and 112.

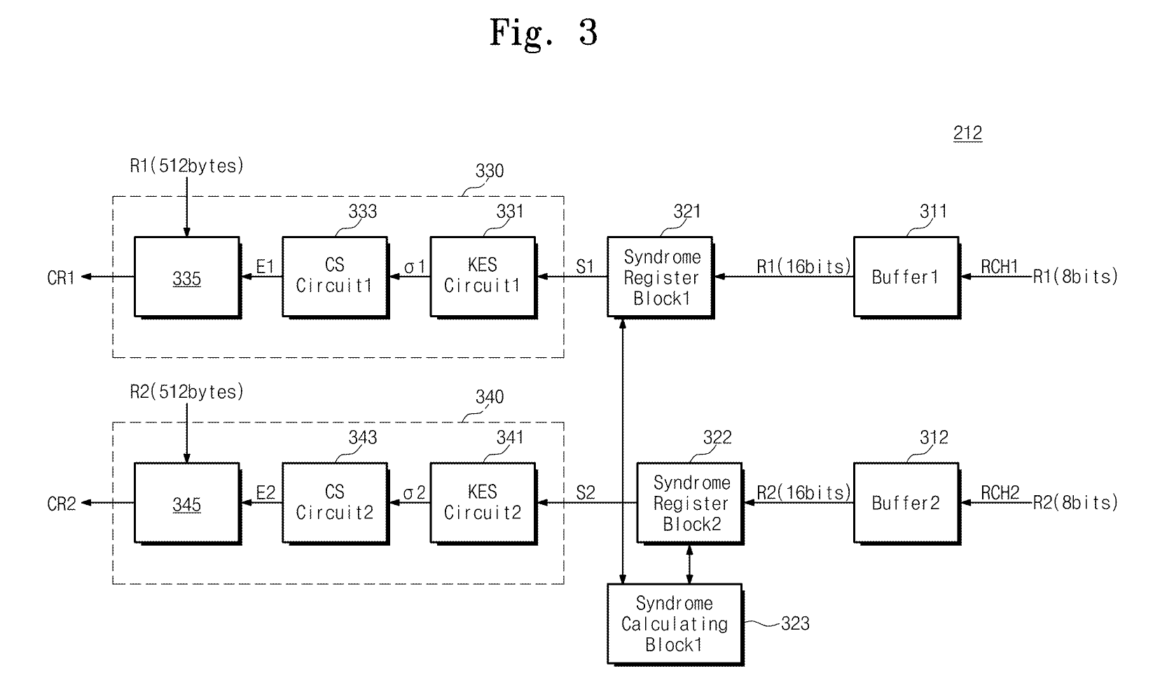

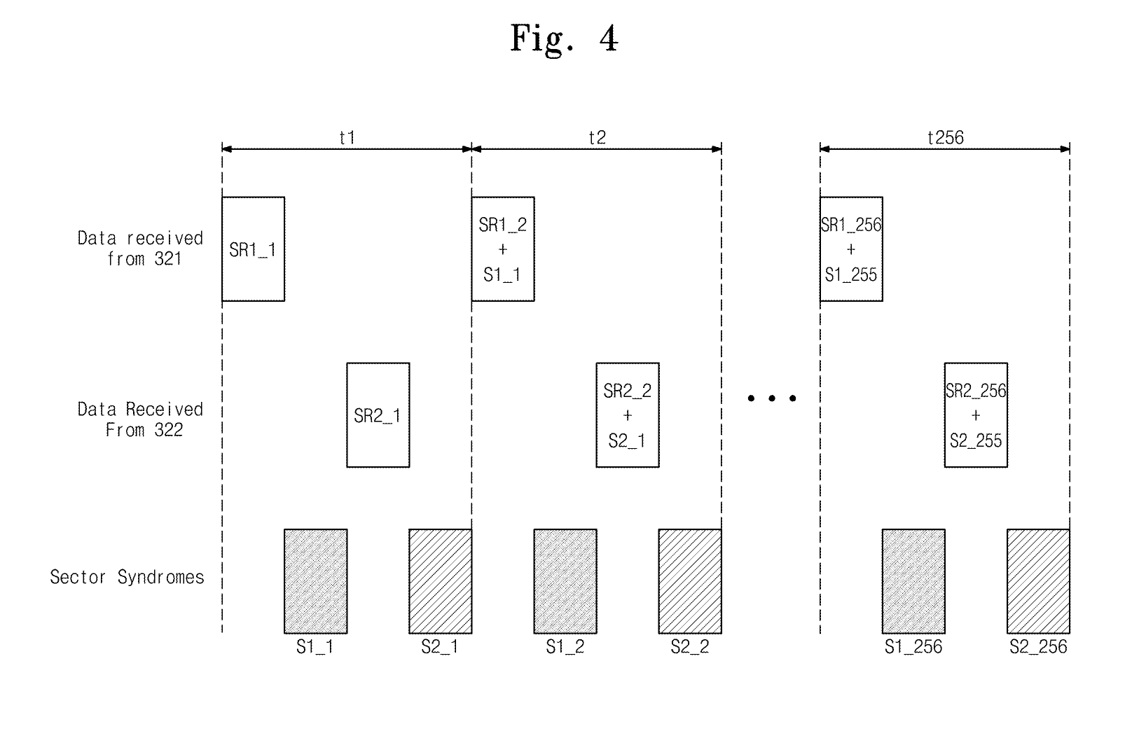

FIG. 3 is a block diagram of decoding unit 212 according to an embodiment of the inventive concept, and FIG. 4 is a timing diagram for a syndrome calculating process of a syndrome calculating block illustrated in FIG. 3.

Referring to FIG. 3, decoding unit 212 comprises first and second buffers 311 and 312, first and second syndrome register blocks 321 and 322, a syndrome calculating block 323, and first and second error correcting blocks 330 and 340.

First and second buffers 311 and 312 are connected with first and second read channels RCH1 and RCH2, respectively. First and second buffers 311 and 312 receive first and second read data R1 and R2 in units of a predetermined number of bits. For example, first and second nonvolatile memories 111 and 112 of FIG. 1 may comprise eight input/output data pins, and first and second read data R1 and R2 may be transferred in units of eight bits, i.e., one byte. Where each of first and second read data R1 and R2 is received in byte units, it can be formed of 512 bytes.

First and second buffers 311 and 312 are connected with first and second syndrome register blocks 321 and 322. First buffer 311 sends first read data R1 to first syndrome register block 321 in a sector unit (e.g., 16 bits). That is, first buffer 311 temporarily stores first read data R1 received in a unit of a predetermined number of bits and outputs read data R1 in sector units. In some embodiments, the sector unit is determined by multiplying the number of channels (e.g., 2) by the predetermined number of bits (e.g., 8 bits). Similarly, second buffer 312 sends second read data R2 to second syndrome block 322 in a sector unit.

First internal buffer unit 211 illustrated in FIG. 2 temporarily stores first and second data R1 and R2 transferred via first and second read channels RCH1 and RCH2, respectively. For example, first internal buffer unit 211 can store each of first and second read data R1 and R2 formed of 512 bytes. First internal buffer unit 211 provides first and second calculating circuits 335 and 345 with first and second read data R1 and R2 each formed of 512 bytes.

First and second syndrome register blocks 321 and 322 are connected with first and second buffers 311 and 312, respectively. First and second syndrome register blocks 321 and 322 receive respective first and second read data R1 and R2 in sector units.

First and second syndrome register blocks 321 and 322 send first and second read data R1 and R2 to syndrome calculating block 323. First and second syndrome register blocks 321 and 322 store first and second syndromes S1 and S2 calculated by syndrome calculating block 323.

First and second syndromes S1 and S2 corresponding to first and second read data R1 and R2 are generated by syndrome calculating block 323. First and second syndrome register blocks 321 and 322 share syndrome calculating block 323. Syndrome calculating block 323 calculates syndromes for first and second read data R1 and R2 which are received in sector units.

Syndrome calculating block 323 performs an operation of producing first syndrome S1 whenever a sector unit of first read data R1 is received. First syndrome register block 321 is updated with the produced first syndrome S1 whenever an operation of producing first syndrome S1 is carried out. Similarly, syndrome calculating block 323 performs an operation of producing second syndrome S2 whenever a sector unit of second read data R2 is received. The produced second syndrome S2 is sent to second syndrome register block 321.

Syndrome calculating block 323 operates by combinational logic and has a current output state determined only by a current input state regardless of a previous input. Accordingly, syndrome calculating block 323 can be shared by first and second syndrome register blocks 321 and 322 using a time division scheme.

For example, where first read data R1 is provided by sending it in 256 units of 16-bits each (256 sector units), syndrome calculating block 323 may produce first syndrome S1 through 256 calculations. Where second read data R2 is provided by sending it in 256 units of 16-bits each (256 sector units), syndrome calculating block 323 produces second syndrome S2 through 256 calculations.

Referring to FIG. 4, which shows a syndrome calculating process of syndrome calculating block 323 in FIG. 3, first read data R1 is assumed to be formed of first through 256^{th} sector read data SR1_1 through SR1_256 each having 16 bits. First through 256^{th} sector read data SR1_1 through SR1_256 is received from first buffer 311. Second read data R2 is assumed to be formed of first through 256^{th} sector read data SR2_1 through SR2_256 each having 16 bits. First through 256^{th} sector read data SR2_1 through SR2_256 is received from second buffer 312.

An i^{th} sector syndrome S1_i is calculated according to the (i−1)^{th} sector syndrome S1_i−1 and the i^{th} sector read data SR1_i. A j^{th} sector syndrome S2_j is calculated according to the (j−1)^{th} sector syndrome S2_j−1 and the j^{th} sector read data SR2_j.

First through 256^{th} sector read data SR1_1 through SR1_256 is provided from first syndrome register block 321 to syndrome calculating block 323. First through 256^{th} sector read data SR2_1 to SR2_256 is provided from second syndrome register block 322 to syndrome calculating block 323.

The timing for providing sector read data from first syndrome register block 321 may be different from the timing for providing sector read data from second syndrome register block 322.

In a first time interval t1, first sector read data SR1_1 is received from first syndrome register block 321, and syndrome calculating block 323 produces first sector syndrome S1_1. First sector syndrome S1_1 is stored in first syndrome register block 321. That is, first syndrome register block 321 stores a calculation result of syndrome calculating block 323. Where first sector read data SR2_1 is received from second syndrome register block 322, syndrome calculating block 323 produces first sector syndrome S2_1 based on first sector read data SR2_1. First sector syndrome S2_1 is stored in second syndrome register block 322.

In a second time interval t2, first syndrome register block 321 sends second sector read data SR1_2 and first sector syndrome S1_1 to syndrome calculating block 323. Syndrome calculating block 323 produces second sector syndrome S1_2 based on second sector read data SR1_2 and first sector syndrome S1_1 from first syndrome register block 321. Syndrome calculating block 323 updates first sector syndrome S1_1 in first syndrome register block 321 with second sector syndrome S1_2.

Syndrome calculating block 323 receives second sector read data SR2_2 and first sector syndrome S2_1 from second syndrome register block 322. Syndrome calculating block 323 calculates second sector syndrome S2_2 based on second sector read data SR2_2 and first sector syndrome S2_1. Syndrome calculating block 323 updates first sector syndrome S2_1 in second syndrome register block 322 with second sector syndrome S2_2.

Third through 256^{th} sector syndromes can be calculated in a manner similar to the first and second sector syndromes as described above.

In a 256^{th} time interval t256, syndrome calculating block 323 receives 256^{th} sector read data SR1_{—}256 and 255^{th} sector syndrome S1_255 from first syndrome register block 321. Syndrome calculating block 323 calculates the 256^{th} sector syndrome S1_256 based on 256^{th} sector read data SR1_256 and 255^{th} sector syndrome S1_255. First syndrome register block 321 is updated by 256^{th} sector syndrome S1_256. The 256^{th} sector syndrome S1_256 stored in first syndrome register block 321 is first syndrome S1.

Syndrome calculating block 323 calculates 256^{th} sector syndrome S2_256 based on 256^{th} sector read data SR2_256 and 255^{th} sector syndrome S2_255 from second syndrome register block 322. Second syndrome register block 322 is updated by 256^{th} sector syndrome S2_256. The 256^{th} sector syndrome S2_256 is second syndrome S2.

As described in FIG. 4, syndrome calculating block 323 calculates first and second syndromes S1 and S2 with respect to first and second read data R1 and R2, respectively, using a time division scheme. Syndrome calculating block 323 is shared in the time division scheme by first and second syndrome register blocks 321 and 322.

First and second syndromes S1 and S2 comprise error information for first and second read data R1 and R2, respectively. In some embodiments, first and second syndromes S1 and S2 comprise error locations, error patterns, and error sizes. Accordingly, it is possible to detect error bits in first and second read data R1 and R2, determine a related error correction probability, and correct errors using first and second syndromes S1 and S2, respectively.

Referring again to FIG. 3, first syndrome register block 321 sends first syndrome S1 to first error correcting block 330, and second syndrome register block 322 sends second syndrome S2 to second error correcting block 340.

First error correcting block 330 corrects errors in first read data R1 based on first syndrome S1 and produces first corrected read data CR1. Similarly, second error correcting block 340 corrects errors in second read data R2 based on second syndrome S2 and produces second corrected read data CR2. Although FIG. 3 illustrates first and second error correcting blocks 330 and 340 configured according to the BCH code, first and second error correcting blocks 330 and 340 can be configured according to other error correction codes such as the RS code, the turbo code, or the LDPS code.

First error correcting block 330 comprises a first key equation solving (KES) circuit 331, a first Chien Search (CS) circuit 333, and a first calculating circuit 335.

First KES circuit 331 calculates a first error location polynomial σ1 using first syndrome S1. For example, first KES circuit 331 can determine a coefficient of first error location polynomial σ1. First error location polynomial σ1 is sent to first CS circuit 333.

First CS circuit 333 calculates a first error correction vector E1 using first error location polynomial σ1. First CS circuit 333 calculates roots of first error location polynomial σ1. First CS circuit 333 calculates error sizes each corresponding error locations searched by first error location polynomial σ1. First CS circuit 333 provides first error correction vector E1 to first calculating circuit 335.

First calculating circuit 335 receives first read data R1 from first internal buffer unit 211 (See, e.g., FIG. 2). First calculating circuit 335 corrects errors in first read data R1 by multiplying first read data R1 by first error correction vector E1. First calculating circuit 335 outputs first corrected read data CR1.

Second error correcting block 340 comprises second KES circuit 341, second CS circuit 343, and second calculating circuit 345. Second KES circuit 341 calculates second error location polynomial σ2 using second syndrome S2. In some embodiments, first and second KES circuits 331 and 341 are implemented using a Euclidean Algorithm (EA), a Modified Euclidean (ME) algorithm, or a Berlecamp-Massay (BM) algorithm.

Second CS circuit 343 calculates error locations and sizes using second error correction polynomial σ2 to produce second error correction vector E2. In some embodiments, second CS circuit 343 is implemented using the CS algorithm. Second calculating circuit 345 produces second corrected read data CR2 by multiplying second read data R2 by second error correction vector E2.

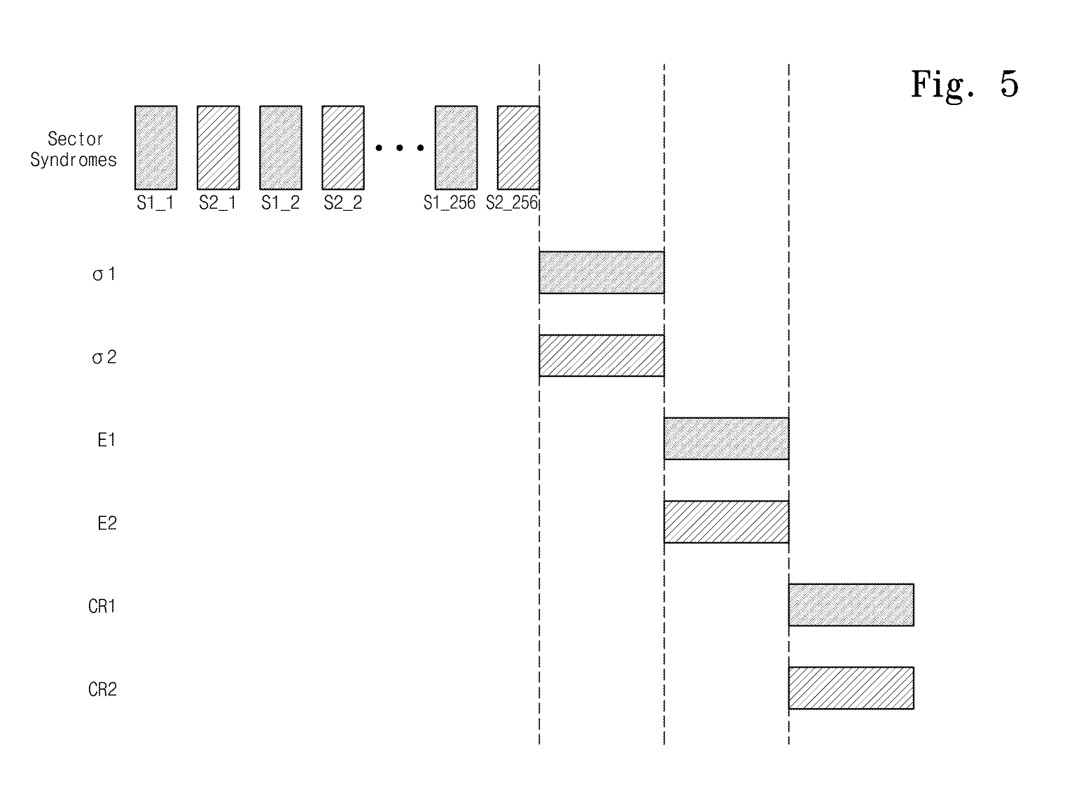

FIG. 5 is a timing diagram illustrating corrected first and second read data CR1 and CR2, which have been corrected by decoding unit 212 of FIG. 3, according to an embodiment of the inventive concept.

Referring to FIGS. 3 and 5, a syndrome calculating block 323 calculates first through 256^{th} sector syndromes S1_1 to S1_256 based on first read data R1 transferred in sector units. Further, syndrome calculating block 323 calculates first through 256^{th} sector syndromes S2_1 through S2_256 based on second read data R2 transferred in sector units. First and second syndrome register blocks 321 and 322 share syndrome calculating block 323 in the time division scheme.

First and second error location polynomials σ1 and σ2 are calculated according to first and second syndromes S1 and S2. First and second error correction vectors E1 and E2 are calculated following calculation of first and second error location polynomials σ1 and σ2. First and second corrected read data CR1 and CR2 are produced based on first and second error correction vectors E1 and E2, respectively.

As indicated above, first and second syndrome register bocks 321 and 322 can share syndrome calculating block 323 using a time division scheme. Accordingly, first and second syndromes S1 and S2 of first and second read data R1 and R2 received through two channels can be calculated by one syndrome calculating block 323, making it possible to provide an ECC decoder 210 occupying a smaller area. In addition, first and second buffers 311 and 312 are included to provide read data in sector units. Although calculation of first and second syndromes S1 and S2 is performed by one syndrome calculating block 323, these syndromes can be calculated in a relatively efficient manner as described above.

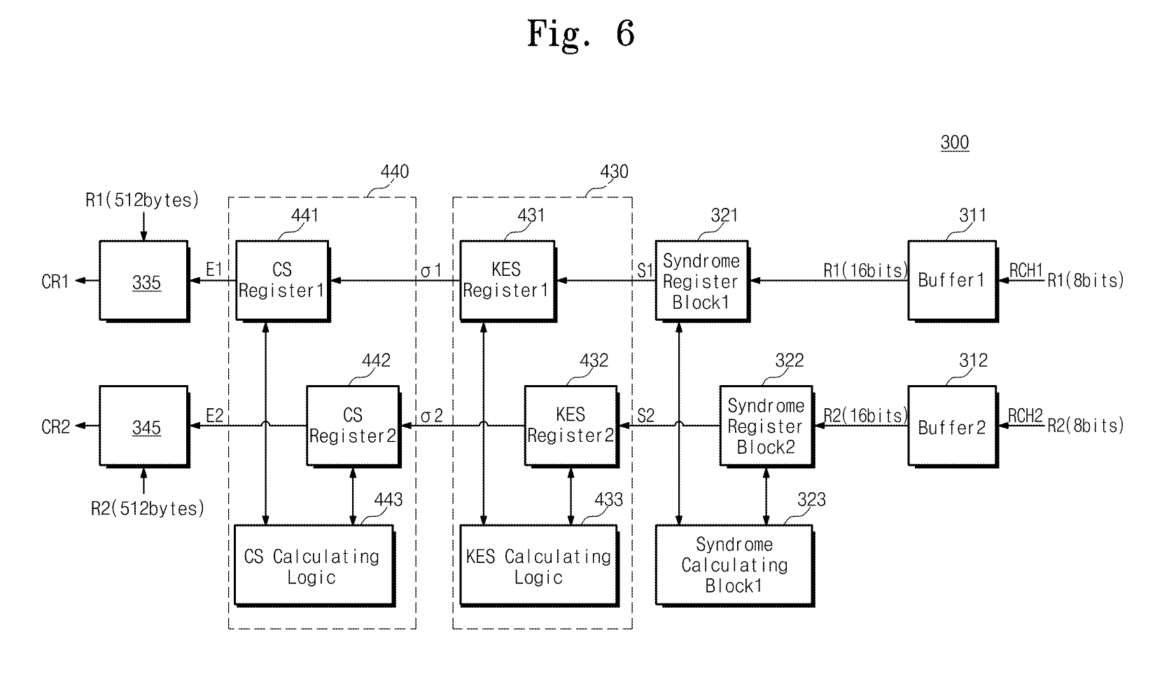

FIG. 6 is a block diagram of a decoding unit 300 according to another embodiment of the inventive concept. Decoding unit 300 can be used as an alternative to decoding unit 212 of FIG. 2. In addition, decoding unit 300 has many of the same features as decoding unit 212 of FIG. 3, so a detailed description of these features will be omitted in order to avoid redundancy.

Referring to FIG. 6, decoding unit 300 comprises first and second buffers 311 and 312, first and second syndrome register blocks 321 and 322, syndrome calculating block 323, first and second algorithm calculating blocks 430 and 440, and first correction calculating circuits 335 and 345.

First and second algorithm calculating blocks 430 and 440 are implemented with a BCH code. However, decoding unit 300 can comprise one or more algorithm calculating blocks implemented according to other types of codes, such as an RS code, a turbo code, and an LDPC code.

First algorithm calculating block 430 receives first and second syndromes S1 and S2, and it obtains first and second error location polynomials σ1 and σ2 based on first and second syndromes S1 and S2. First algorithm calculating block 430 comprises first and second KES registers 431 and 432 and KES calculating logic 433.

First KES register 431 temporarily stores first syndrome S1, which is sent to KES calculating logic 433. KES calculating logic 433 obtains first error location polynomial σ1 using first syndrome S1. First error location polynomial σ1 is transferred to first KES register 431, which temporarily stores first error location polynomial σ1.

Similarly, second KES register 432 provides KES calculating logic 433 with second syndrome S2 received from second syndrome register block 322. For example, second syndrome S2 can be sent to KES calculating logic 433 after first error location polynomial σ1 is sent from KES calculating logic 433 to first KES register 431. KES calculating logic 433 obtains second error location polynomial σ2 using second syndrome S2 and sends it to second KES register 432.

KES calculating logic 433 calculates error location polynomials corresponding to input syndromes, based on a predetermined algorithm. KES calculating logic 433 issues first error location polynomial σ1 upon an input of first syndrome S1 and second error location polynomial σ2 upon an input of second syndrome S2.

Second algorithm calculating block 440 comprises first and second CS registers 441 and 442 and CS calculating logic 443. First and second CS registers 441 and 442 temporarily store first and second error location polynomials σ1 and σ2.

First CS register 441 transfers first error location polynomial σ1 to CS calculating logic 443, and CS calculating logic 443 calculates roots of first error location polynomial σ1. Further, CS calculating logic 443 may calculate error sizes corresponding to error locations searched through the error location polynomial. CS calculating logic 443 provides first CS register 441 with first error correction vector E1 for correcting errors.

Similarly, second CS register 442 transfers second error location polynomial σ2 to CS calculating logic 443. For example, CS calculating logic 443 may receive second error location polynomial σ2 after first error correction vector E1 is issued from CS calculating logic 443. CS calculating logic 443 calculates roots of second error location polynomial σ2 and error sizes corresponding to searched error locations. CS calculating logic 443 may produce second error location vector E2 based on error locations and sizes.

First error calculating circuit 335 corrects an error in first read data R1 by multiplying first error correction vector E1 and first read data R1. Further, second error calculating circuit 345 may correct an error in second read data R2 by multiplying second error correction vector E2 and second read data R2.

In some embodiments, syndrome calculating block 323, KES calculating logic 433, or CS calculating logic 443 is shared in a time division scheme to perform combinational logic operations on data received via plural channels, respectively. In this manner, it is possible to implement decoding unit 300 with reduced area. First and second syndromes S1 and S2 are stored in first and second syndrome register blocks 321 and 322 according to combinational logic operations. First and second error location polynomials σ1 and σ2 are stored in first and second KES registers 431 and 432, respectively. First and second error correction vectors E1 and E2 are stored in first and second CS registers 441 and 442.

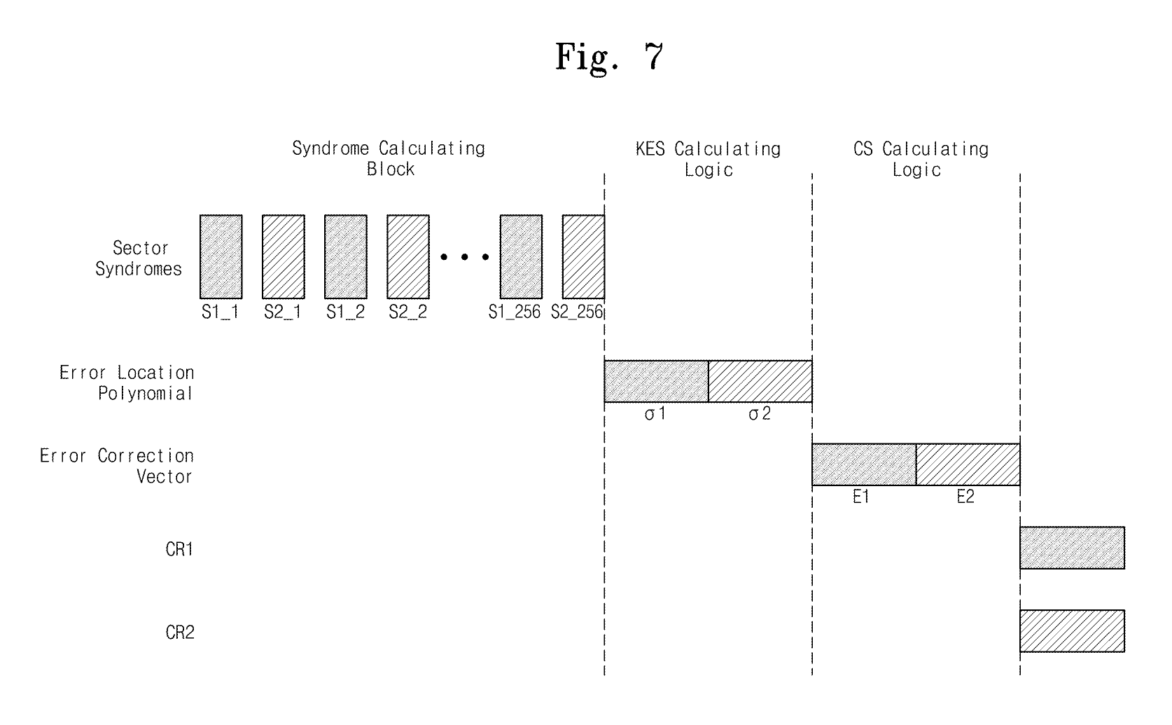

FIG. 7 is a timing diagram for first read data and second read data corrected by decoding unit 300 of FIG. 6. Referring to FIGS. 6 and 7, syndrome calculating block 323 calculates first through 256^{th} sector syndromes S1_1 through S1_256 in response to first read data R1 received from first syndrome register block 321 in a sector unit. Further, syndrome calculating block 323 calculates first through 256^{th} sector syndromes S2_1 through S2_256 in response to second read data R2 received from second syndrome register block 322 in a sector unit.

KES calculating logic 433 calculates first and second error location polynomials σ1 and σ2 based on first and second syndromes S1 and S2. First and second KES registers 431 and 432 share KES calculating logic 433 in the time division scheme. In particular, first error location polynomial σ1 is calculated according to first syndrome S1 and is temporarily stored in first KES register 431. KES calculating logic 433 receives second syndrome S2 from second KES register 431. KES calculating logic 433 calculates second error location polynomial σ2 according to second syndrome S2.

CS calculating logic 443 calculates first and second error location vectors E1 and E2 based on first and second error location polynomials σ1 and σ2. First and second CS registers 441 and 442 share CS calculating logic 443 in the time division scheme. CS calculating logic 443 calculates first error correction vector E1 and then second error correction vector E2.

Errors of first and second read data R1 and R2 are corrected according to respective first and second error correction vectors E1 and E2. This produces respective first and second corrected read data CR1 and CR2.

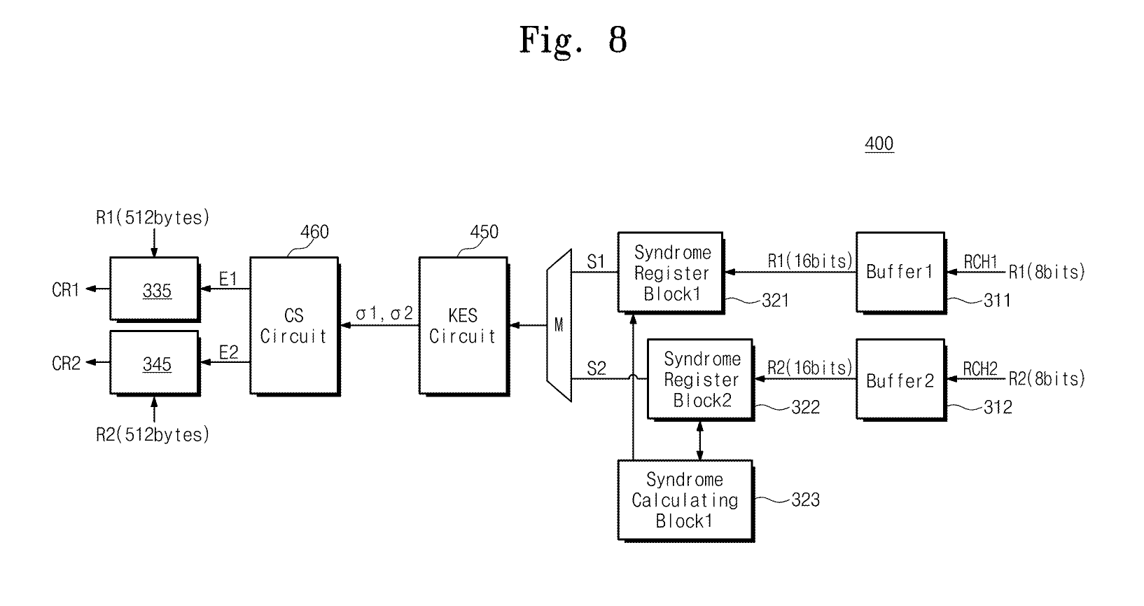

FIG. 8 is a block diagram of a decoding unit 400 according to another embodiment of the inventive concept. Decoding unit 400 can be used as an alternative to decoding unit 212 of FIG. 2. Moreover, decoding unit 400 has many of the same features as decoding unit 212 of FIG. 3, so a detailed description of these features will be omitted in order to avoid redundancy.

Referring to FIG. 8, decoding unit 400 comprises first and second buffer units 311 and 312, first and second syndrome register blocks 321 and 322, syndrome calculating block 323, a multiplexer M, a KES circuit 450, a CS circuit 460, and first and second error calculating circuits 335 and 345.

Multiplexer M selects first syndrome S1 or second syndrome S2 to be sent to KES circuit 450. For example, in response to a decoding control signal CTRL1, multiplexer M can transfer first syndrome S1 to KES circuit 450 and then second syndrome S2.

KES circuit 450 calculates an error location polynomial on a received syndrome. Where first and second syndromes S1 and S2 are received in sequence, KES circuit 450 calculates first error location polynomial σ1 and then second error location polynomial σ2. CS circuit 460 sequentially generates first and second error correction vectors E1 and E2 in response to first and second error location polynomials σ1 and σ2.

First error correction vector E1 is sent to first error calculating circuit 335, and second error correction vector E2 is sent to second error calculating circuit 345. In some embodiments, in response to decoding control signal CTRL1 (refer to FIG. 2), CS circuit 460 transfers first and second error correction vectors E1 and E2 to first and second error calculating circuits 335 and 345, respectively.

First error calculating circuit 335 produces first corrected read data CR1 obtained by multiplying first error correction vector E1 and first read data R1. Second error calculating circuit 345 produces second corrected read data CR2 obtained by multiplying second error correction vector E2 and second read data R2.

As an alternative to the configuration of FIG. 8, it is possible to form decoding unit 400 with one correction circuit. In such a decoding unit, first and second error correction vectors E1 and E2 can be provided sequentially to the one correction circuit. Further, the one correction circuit may sequentially receive first and second read data R1 and R2. First corrected read data CR1 may be produced according to first error correction vector E1 and first read data R1, and second corrected read data CR2 may be produced according to second error correction vector E2 and second read data R2.

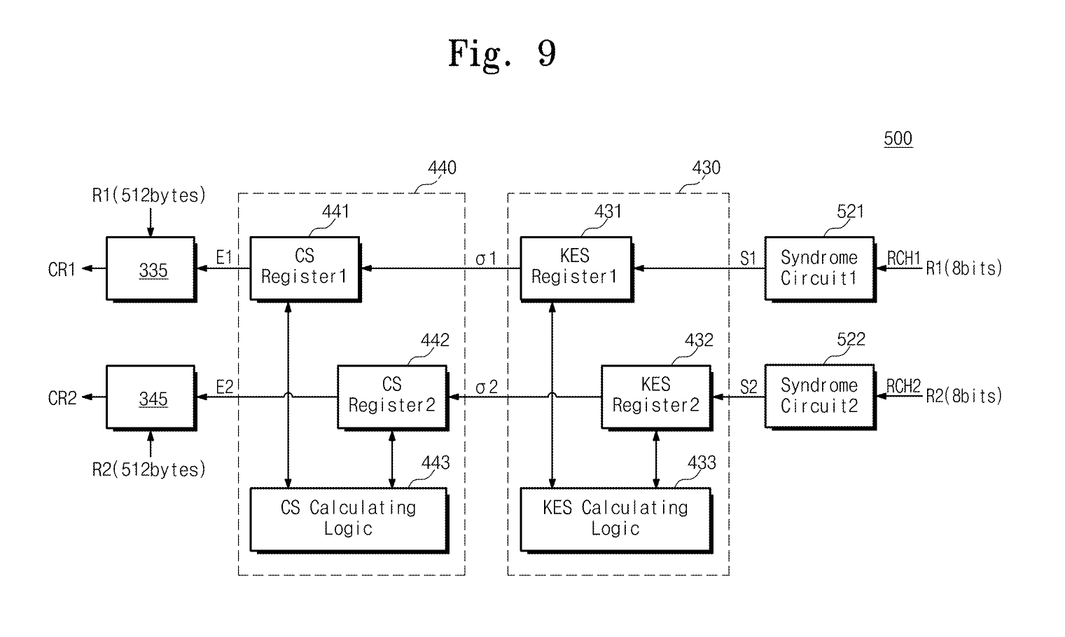

FIG. 9 is a block diagram of a decoding unit 500 according to another embodiment of the inventive concept. Decoding unit 500 can be used as an alternative to decoding unit 212 of FIG. 2. Moreover, decoding unit 500 has many of the same features as decoding unit 212 of FIG. 3 and decoding unit 400 of FIG. 6, so a detailed description of these features will be omitted in order to avoid redundancy.

Referring to FIG. 9, decoding unit 500 comprises first and second syndrome circuits 521 and 522, first and second algorithm calculating blocks 430 and 440, and first and second correction calculating circuits 335 and 345.

First and second syndrome circuits 521 and 522 are connected with first and second read channels RCH1 and RCH2. First and second syndrome circuits 521 and 522 receive first and second read data R1 and R2 in a unit of a predetermined number of bits. For example, first and second syndrome circuits 521 and 522 receive first and second read data R1 and R2 each transferred in a byte unit.

First syndrome circuit 521 calculates first syndrome S1 according to first read data R1. First syndrome circuit 521 performs an operation for obtaining first syndrome S1 whenever first read data R1 is received in a unit of a predetermined number of bits. In some embodiments, first syndrome circuit 521 comprise calculation logic for calculating first syndrome S1, where the calculation logic calculates first syndrome S1 according to first read data R1.

Similarly, second syndrome circuit 522 performs an operation of obtaining second syndrome S2 whenever second read data R2 is received by a unit of a predetermined number of bits. In some embodiments, second syndrome circuit 522 comprises calculation logic for calculating second syndrome S2.

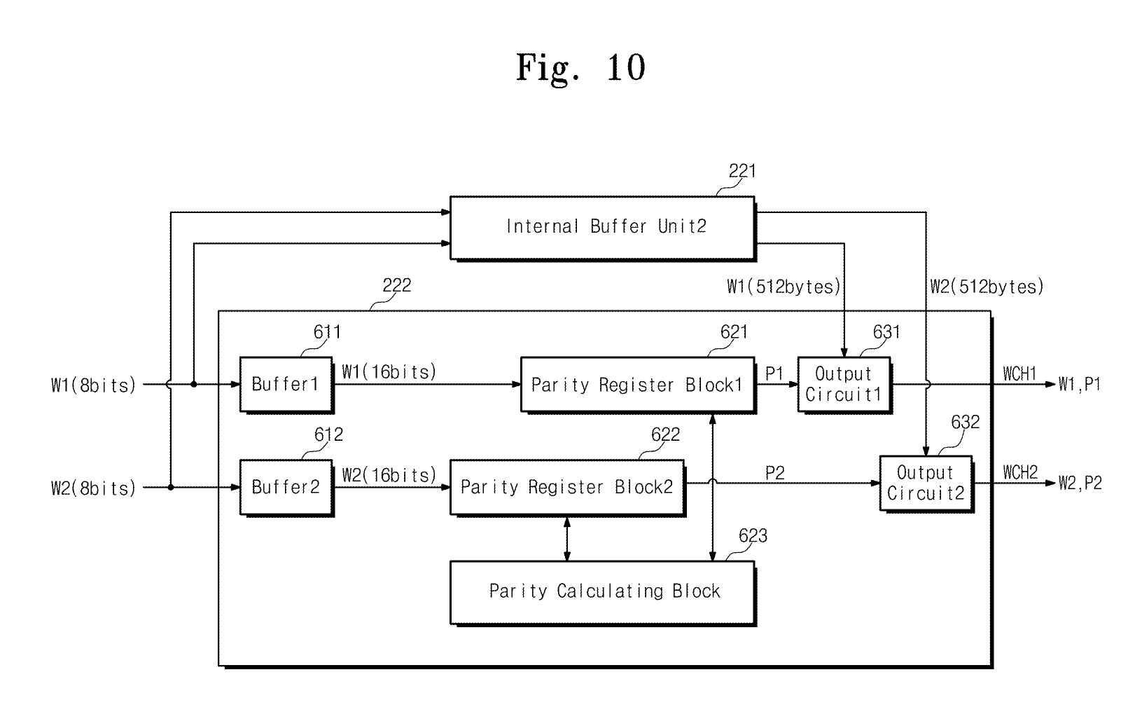

FIG. 10 is a block diagram of second internal buffer unit 221 and encoding unit 222 of FIG. 2.

Referring to FIG. 10, second internal buffer unit 221 temporarily stores first and second write data W1 and W2 which are received in a unit of a predetermined number of bits. For example, it is assumed that each of first and second write data W1 and W2 is transferred 512 times in a byte unit. Second internal buffer unit 221 stores first and second write data W1 and W2 each comprising 512 bytes. Second internal buffer unit 221 provides first and second write data W1 and W2 to first and second output circuits 631 and 632, respectively.

An encoding unit 222 comprises first and second buffers 611 and 612, a parity calculating block 623, and first and second output circuits 631 and 632.

First and second buffers 611 and 612 store first and second write data W1 and W2 which are received in a unit of a predetermined number of bits (e.g., 8 bits). First and second buffers 611 and 612 transfer respective first and second write data W1 and W2 in a sector unit (e.g., 16-bits).

For example, it is assumed that first and second write data W1 and W2 are sent to first and second buffers 611 and 612 in a byte unit. First buffer 611 outputs first write data W1 in a 16-bit unit. Second buffer 612 outputs second write data W2 in a 16-bit unit.

First and second parity register blocks 621 and 622 receive first and second write data W1 and W2. First write data W1 is transferred from first parity register block 621 to parity calculating block 623 in a sector unit. Parity calculating block 623 generates first parity bits P1 whenever first write data W1 is received in a sector unit. The result is stored in first parity register block 621. In some embodiments, parity calculating block 623 performs an operation of generating parity bits according to error correction codes such as a BCH code, an RS code, a turbo code, an LDPC code, or a CRC code.

Second write data W2 is sent from second parity register block 622 to parity calculating block 623 in a sector unit. Parity calculating block 623 performs an operation of generating second parity bits P2 whenever second write data W1 is received in a sector unit. Operations of calculating the first and second parity bits P1 and P2 may be performed independently. That is, first and second parity register blocks 621 and 622 share parity calculating block 623 in the time division scheme.

Where first and second write data W1 and W2 are transferred 256 times by a 16-bit unit, parity calculating block 623 may perform an operation of generating first parity bits P1 256 times. First parity bits P1 are formed of data stored in first parity register block 621 after this operation is repeated 256 times. Parity calculating block 623 performs an operation of generating second parity bits P2 256 times. Second parity bits P2 are formed of data stored in second parity register block 622 after this operation is repeated 256 times. First parity bits P1 are parity bits corresponding to first write data W1 formed of 512 bytes. Second parity bits P2 are parity bits corresponding to second write data W2 formed of 512 bytes.

First output circuit 631 transfers first parity bits P1 and first write data W1 through first write channel WCH1, and second output circuit 632 transfers second parity bits P2 and second write data W2 through second write channel WCH2.

In some embodiments, first and second parity register blocks 621 and 622 share parity calculating block 623 in the time division scheme. Accordingly, it possible to form ECC encoder 220 with an improved level of integration.

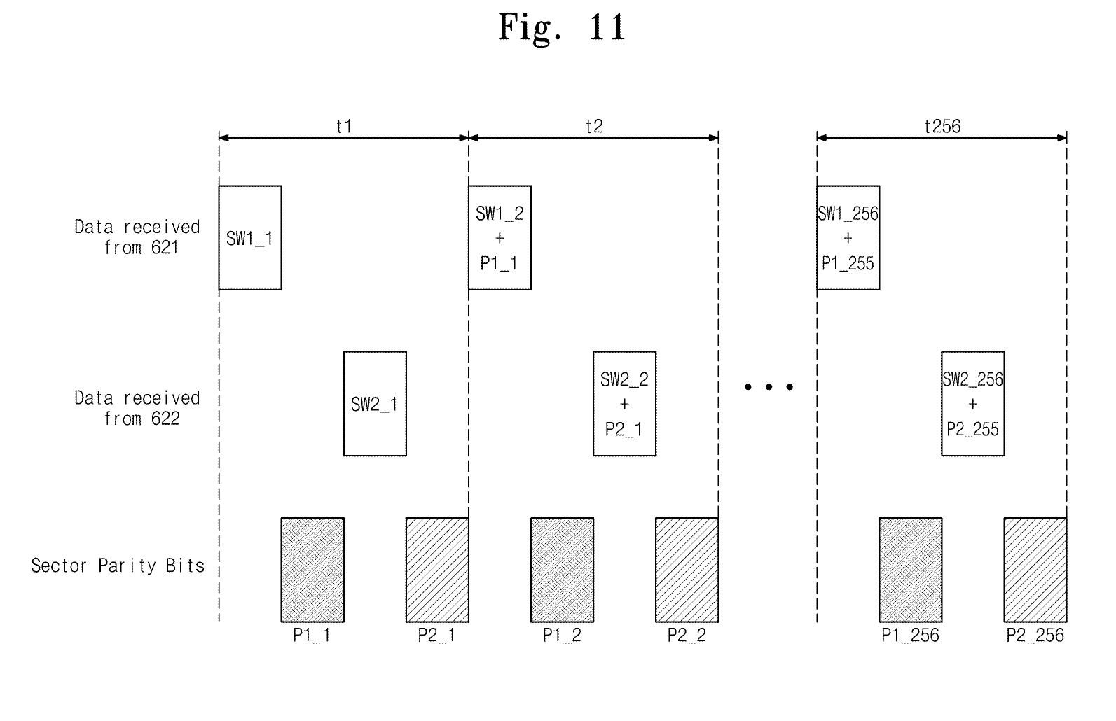

FIG. 11 is a timing diagram showing the first parity bits and the second parity bits generated by encoding unit 222 of FIG. 10. It is assumed that first write data W1 comprises first through 256^{th} sector write data SW1_1 through SW1_256 each formed of 16 bits. It is further assumed that second write data W2 comprises first through 256^{th} sector write data SW2_1 through SW2_256 each formed of 16 bits.

A parity calculating block 623 calculates first parity bits P1 using first write data W1, which is provided in a sector unit. Parity calculating block 623 calculates second parity bits P2 using second write data W2, which is provided in a sector unit.

The i^{th} sector parity bits P1_i are updated whenever an operation of calculating first parity bits P1 is performed. The j^{th} sector parity bits P1_j are updated whenever an operation of calculating second parity bits P2 is performed.

First through 256^{th} sector write data SW1_1 through SW1_256 are provided from first parity register block 621 to parity calculating block 623. First through 256^{th} sector write data SW2_1 through SW2_256 are provided from second parity register block 622 to parity calculating block 623. The timing when a plurality of write data is provided from first parity register block 621 is different from the timing when a plurality of write data is provided from second parity register block 622.

In a first time interval t1, where first sector write data SW1_1 is received, syndrome calculating block 323 generates first sector parity bits P1_1. First sector parity bits P1_1 are stored in first syndrome register block 321.

Where first sector write data SW2_1 is received, syndrome calculating block 323 generates first sector parity bits P2_1. First sector parity bits P2_1 are stored in second syndrome register block 322.

In a second time interval t2, first parity register block 621 transfers second sector write data SW1_2 and first sector parity bits P1_1 to a parity calculating block 623. Parity calculating block 623 calculates second sector parity bits P1_2 according to second sector write data SW1_2 and first sector parity bits P1_{—}1. Parity calculating block 623 updates first sector parity bits P1_1 in first parity register block 621 with second sector parity bits P1_2.

Parity calculating block 623 receives second sector write data SW2_2 and first sector parity bits P2_1 from second parity register block 622. Parity calculating block 623 calculates second sector parity bits P2_2 based on second sector write data SW2_2 and first sector parity bits P2_{—}1. Parity calculating block 623 updates first sector parity bits P2_1 in second parity register block 622 with second sector parity bits P2_2.

In other words, parity calculating block 623 performs an operation of generating first parity bits P1 whenever first write data W1 is received in a sector unit. The calculation result is stored in first parity register block 621, which is updated whenever an operating of generating first parity bits P1 is performed. Similarly, parity calculating block 623 performs an operation of generating second parity bits P2 whenever second write data W2 is received in a sector unit.

In a 256^{th} time interval t256, parity calculating block 623 receives 256^{th} sector write data SW1_256 and 255^{th} sector parity bits P1_255 from first parity register block 621. Parity calculating block 623 calculates 256^{th} sector parity bits P1_256 based on 256^{th} sector write data SW1_256 and 255^{th} sector parity bits P1_255. First parity register block 621 is updated with 256^{th} sector parity bits P1_256. The 256^{th} sector parity bits P1_256 are first parity bits P1.

Parity calculating block 623 calculates the 256^{th} sector parity bits P2_256 based on 256^{th} sector write data SW2_256 and 255^{th} sector parity bits P1_255 received from second parity register block 622. Parity calculating block 623 updates the 255^{th} sector parity bits S2_255 in second sector parity bits P2_256 with second parity bits P2.

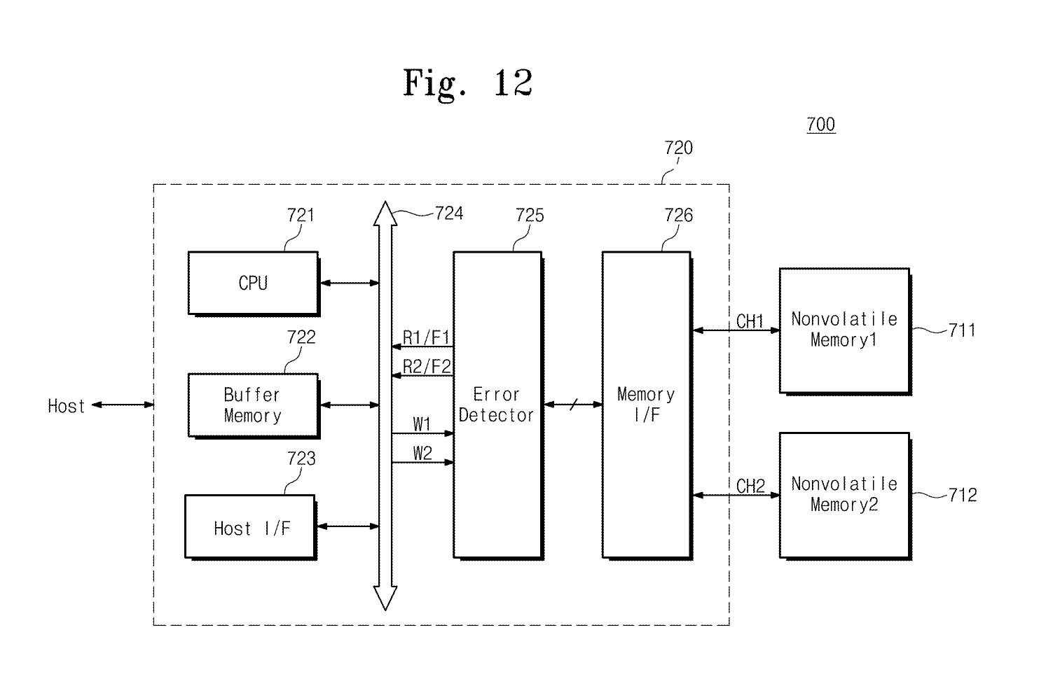

FIG. 12 is a block diagram of a memory system 700 comprising an error detector according to an embodiment of the inventive concept.

Referring to FIG. 12, memory system 700 comprises first and second nonvolatile memories 711 and 712 and a memory controller 720. Memory controller 720 comprises a CPU 721, a buffer memory 722, a host interface 723, a bus 724, an error detector 725, and a memory interface 726. Other features 711, 712, 721, 722, 723, 724, and 726 other than error detector 725 are configured identical to respective features 111, 112, 121, 122, 123, 124, and 126 of FIG. 1, so a description of these features will be omitted in order to avoid redundancy.

Error detector 725 receives first and second write data W1 and W2. Error detector 725 generates parity bits based on first and second write data W1 and W2.

First and second read data R1 and R2 are received via first and second channels CH1 and CH2, respectively. Error detector 725 receives first and second read data R1 and R2 via memory interface 726. error detector 725 detects errors of the first and second read data R1 and R2 and decides transmission of first and second read data R1 and R2.

Where first read data R1 is detected to be erroneous, error detector 725 generates first fail signal F1. Where second read data R2 is detected to be erroneous, error detector 725 generates second fail signal F2. CPU 721 may receive first and second fail signals F1 and F2.

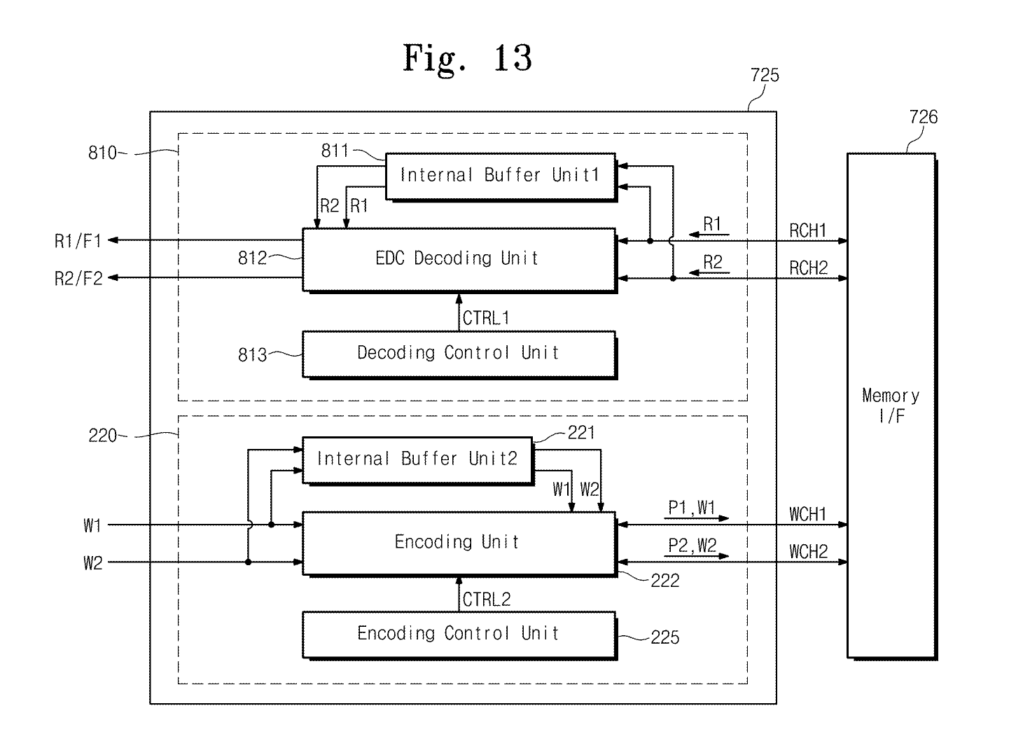

FIG. 13 is a block diagram of error detector 725 and memory interface 726 of FIG. 12 according to an embodiment of the inventive concept.

Referring to FIG. 13, error detector 725 comprises an ECC decoder 810 and ECC encoder 220. ECC encoder 220 can be configured identical to ECC encoder 220 of FIG. 2. That is, ECC encoder 220 comprises second internal buffer unit 221 for storing the first and second write data W1 and W2 received in a unit of a predetermined number of bits, an encoding unit 222 for generating first and second parity bits P1 and P2, and an encoding control unit 225 for controlling encoding unit 222. In some embodiments, encoding unit 222 generates first and second parity bits P1 and P2 according to a cyclic redundancy check (CRC) algorithm.

Memory interface 726 connects first and second read channels RCH1 and RCH2 to respective first and second channels CH1 and CH2 (refer to FIG. 12) in a read operation. In a write operation, memory interface 726 connects first and second write channels WCH1 and WCH2 to first and second channels CH1 and CH2, respectively. That is, first and second channels CH1 and CH2 are connected to error detecting decoder 810 in a read operation and to error detecting encoder 220 in a write operation.

ECC decoder 810 comprises first internal buffer unit 811, an EDC decoding unit 812, and a decoding control unit 813. First internal buffer unit 811 receives first and second read data R1 and R2 from first and second read channels RCH1 and RCH2, respectively. First internal buffer unit 811 temporarily stores first and second read data R1 and R2. For example, first internal buffer unit 811 may store first and second read data R1 and R2, each of which is formed of 512 bytes. Each of the first and second read data R1 and R2 may be provided to internal buffer unit 811 by transferring it to internal buffer unit 811 512 times in a byte unit.

EDC decoding unit 812 detects errors of first and second read data R1 and R2. EDC decoding unit 812 operates responsive to a decoding control signal CTRL1 received from decoding control unit 813. For example, EDC decoding unit 812 decodes first and second read data R1 and R2 in response to decoding control signal CTRL1 and detects errors of first and second read data R1 and R2.

EDC decoding unit 212 issues first read data R1 or first fail signal F1 according to a detection result. EDC decoding unit 212 issues second read data R2 or second fail signal F2 according to a detection result.

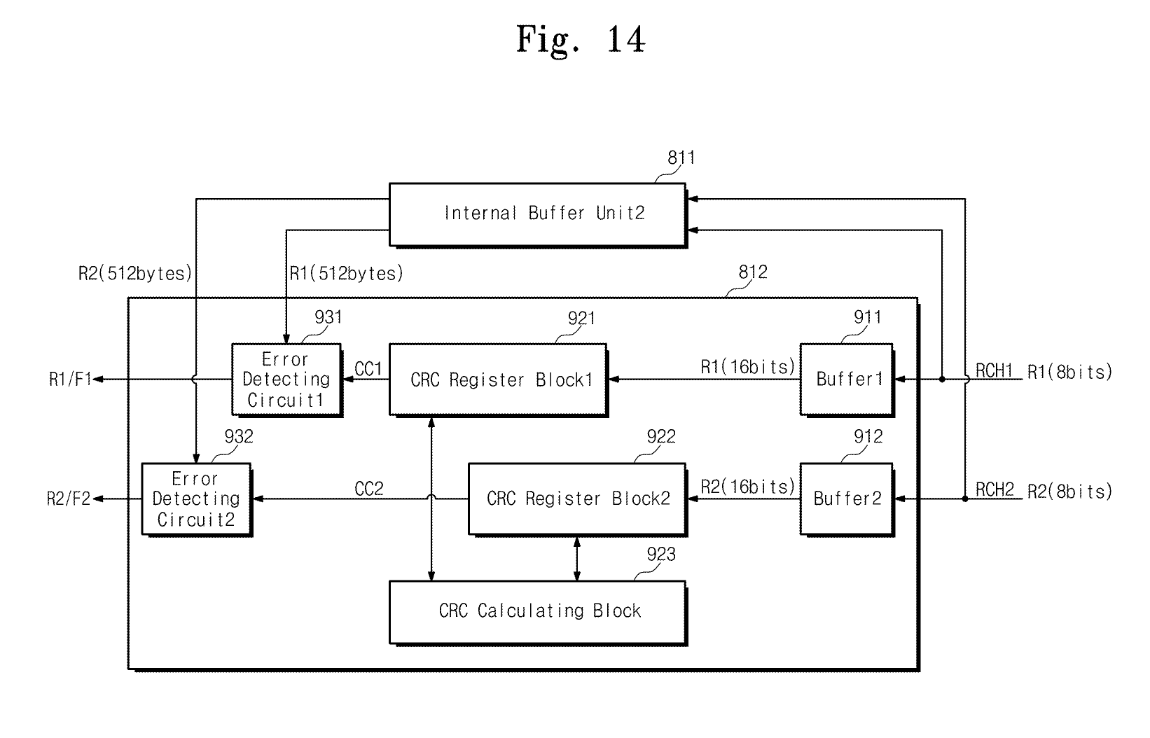

FIG. 14 is a block diagram of first internal buffer unit 811 and EDC decoding unit 812 of FIG. 13 according to an embodiment of the inventive concept.

Referring to FIG. 14, EDC decoding unit 812 comprises first and second buffers 911 and 912, first and second CRC register blocks 921 and 922, a CRC calculating block 923, and first and second error detecting circuits 931 and 932.

First and second buffers 911 and 912 are connected with first and second read channels RCH1 and RCH2, respectively. First and second buffers 911 and 912 receive respective first and second read data R1 and R2 in a unit of a predetermined number of bits (e.g., 8 bits). First and second buffers 911 and 912 output first and second read data R1 and R2 in a sector unit (e.g., 16 bits).

First and second CRC register blocks 921 and 922 receive first and second read data. CRC calculating block 923 generates first and second CRC codes CC1 and CC2 based on first and second read data R1 and R2, respectively. In some embodiments, CRC calculating block 923 produces first and second CRC codes CC1 and CC2 according to a CRC algorithm.

First CRC register block 921 provides CRC calculating block 923 with first read data R1 transferred in a sector unit. CRC calculating block 923 performs an operation of generating first CRC code CC1 where the sector unit of first read data R1 is transferred from first CRC register block 921. The result is stored in first CRC register block 921 and updated where the operation of generating first CRC code CC1 is performed.

In some embodiments, where transmission of first read data R1 is made by transferring it 256 times in a 16-bit unit, CRC calculating block 923 repeats the operation of generating first CRC code CC1 256 times. After these 256 operations, first CRC code CC1 is stored in first CRC register block 921.

Similarly, second CRC register block 922 provides second read data to CRC calculating block 923 in a sector unit. CRC calculating block 923 performs an operation of generating second CRC code CC2 where a sector unit of second read data R1 is received. As a result, second CRC code CC2 is stored in second CRC register block 922.

First and second error detecting circuits 931 and 932 receive first and second CRC codes CC1 and CC2, respectively. First and second error detecting circuits 931 and 932 receive first and second read data R1 and R2, respectively. For example, first CRC code CC1 correspond to first read data R1 formed of 512 bytes, and second CRC code CC2 corresponds to second read data R2 formed of 512 bytes.

First error detecting circuit 931 generates first read data R1 or first fail signal F1 according to first CRC code CC1, and second error detecting circuit 932 generates second read data R2 or second fail signal F2 according to second CRC code CC2.

In the embodiment of FIG. 14, errors in first and second read data R1 and R2 received from two channels are detected using one CRC calculating block 923. First and second CRC register blocks 921 and 922 share CRC calculating block 923 in the time division scheme. Accordingly, ECC decoder 810 can be implemented with an improved level of integration.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. An error checking and correcting (ECC) circuit, comprising:
first and second syndrome register blocks that receive respective first and second read data transferred via different channels, wherein the first read data comprises multiple units of first sector read data and the second read data comprises multiple units of second sector read data;
a syndrome calculating block commonly connected to the first and the second syndrome register blocks, wherein the syndrome calculating block performs first operations based on each unit of the first sector read data to update the first syndrome register block with results of the first operations, and performs second operations based on each unit of the second sector read data to update the second syndrome register block with results of the second operations,
wherein first and second syndromes are determined according to the updated results stored in the first and second syndrome register blocks, and errors in the first and second read data are corrected according to the first and second syndromes.

2. The ECC circuit of claim 1, wherein the syndrome calculating block performs the first and second operations using a time division scheme.

3. The ECC circuit of claim 1, further comprising a first buffer that receives the first read data and transfers the first sector read data to the first syndrome register block in units of a predetermined number of bits; and
a second buffer that receives the second read data and transfers the second sector read data to the second syndrome register block in units of the predetermined number of bits.

4. The ECC circuit of claim 1, wherein the syndrome calculating block performs a first operation based on the first sector read data after each unit of the first sector read data is received and updates the first syndrome register block with a result of the first operation, and performs a second operation based on the second sector read data after each unit of the second sector read data is received and updates the second syndrome register block with a result of the second operation.

5. The ECC circuit of claim 1, wherein the first and second syndrome register blocks transfer the first and second sector read data to the syndrome calculating block using different timing.

6. The ECC circuit of claim 1, further comprising:
an internal buffer unit that temporarily stores the first and second read data;
a first error correcting block that receives the first read data from the internal buffer unit and corrects errors of the first read data according to the first syndrome; and
a second error correcting block that receives the second read data from the internal buffer unit and corrects errors of the second read data according to the second syndrome.

7. The ECC circuit of claim 1, further comprising:
first and second key equation solving (KES) registers that temporarily store the respective first and second syndromes; and
KES calculating logic that calculates a first error location polynomial according to the first syndrome to store the first error location polynomial in the first KES register, and calculates a second error location polynomial according to the second syndrome to store the second error location polynomial in the second KES register, wherein errors in the first and second read data are corrected according to the respective first and second error location polynomials.

8. The ECC circuit of claim 7, wherein the KES calculating logic makes calculations of the first and second error location polynomials in a time division scheme.

9. The ECC circuit of claim 7, further comprising:
first and second Chien search (CS) registers that temporarily store the respective first and second error location polynomials; and
CS calculating logic that calculates a first error correction vector according to roots of the first error location polynomial to store the first error correction vector in the first CS register, and calculates a second error correction vector according to roots of the second error location polynomial to store the second error correction vector in the second CS register, wherein errors in the first and second read data are corrected according to the first and second error correction vectors.

10. The ECC circuit of claim 9, wherein the CS calculating logic makes calculations of the first and second error correction vectors in a time division scheme.

11. The ECC circuit of claim 9, further comprising:
a first error calculating circuit that multiplies the first read data and the first error correction vector to generate first corrected read data; and
a second error calculating circuit that multiplies the second read data and the second error correction vector to generate second corrected read data.

12. The ECC circuit of claim 11, further comprising:
an internal buffer unit that temporarily stores the first and second read data transferred via the different channels, and provides the first and second read data to the first and second error calculating circuits, respectively.

13. A memory system, comprising:
a plurality of channels;
a plurality of memories connected to the plurality of channels, respectively; and
an error checking and correcting (ECC) circuit that performs an error detecting and correcting operation on data transferred via the plurality of channels,
wherein the ECC circuit comprises a plurality of register blocks corresponding to the respective channels, and a calculation block commonly connected to the first and the second syndrome register blocks, wherein the calculation block performs combinational logic operations to data received via the respective channels so as to be shared in a time division scheme.

14. The memory system of claim 13, wherein the calculation block stores results of combinational logic operations performed on data received via the plurality of channels in the plurality of register blocks.

15. The memory system of claim 14, wherein syndromes of the data received via the plurality of channels are determined according to the results of the combinational logic operations, and errors in the data transferred via the plurality of channels are corrected according to the syndromes.

16. A method of operating a memory system comprising a plurality of nonvolatile memory devices, the method comprising:
(a) receiving first read data from a first nonvolatile memory device through a first channel, and receiving second read data from a second nonvolatile memory device through a second channel, wherein the first read data comprises multiple units of first sector read data, and the second read data comprises multiple units of second sector read data;
(b) transmitting a unit of the first sector read data to a first syndrome register block, and transmitting a unit of the second sector read data to a second syndrome register block;
(c) transmitting the unit of the first sector read data to a syndrome calculating block, calculating a first sector syndrome based on the unit of the first sector read data, and transmitting the first sector syndrome to the first syndrome register block; and,
(d) after calculating the first sector syndrome, transmitting the unit of the second sector read data to the syndrome calculating block, calculating a second sector syndrome based on the unit of the second sector read data, and transmitting the second sector syndrome to the first syndrome register block.

17. The method of claim 16, further comprising:
repeating (b), (c), and (d) until a first sector syndrome has been generated for each unit of the first sector read data, and a second sector syndrome has been generated for each unit of the second sector read data;
combining the first sector syndromes to generate a first syndrome, and combining the second sector syndromes to generate a second syndrome; and
transmitting the first syndrome to a first error correcting block, and transmitting the second syndrome to a second error correcting block.

18. The method of claim 17, applying the first syndrome to the first read data to generate corrected first read data, and applying the second syndrome to the second read data to generate corrected second read data.

19. The method of claim 16, wherein the first read data comprises 256 units of first sector read data.

20. The method of claim 18, wherein the applying the first syndrome comprises using a Chien search algorithm or a key equation solving algorithm to generate the corrected first read data, and applying the second syndrome comprises using the Chien search algorithm or the key equation solving algorithm to generate the corrected second read data.
